(19) United States
(12) Patent Application Publication
(10) Pub. No.: US 2022/0310370 A1
(43) Pub. Date: Sep. 29, 2022

(54) ELECTRODE PHASING USING CONTROL PARAMETERS

(71) Applicant: Advanced Energy Industries, Inc., Fort Collins, CO (US)

(72) Inventors: Craig Rappe, Owatonna, MN (US); Robert B. Huff, Fort Collins, CO (US)

(21) Appl. No.: 17/209,479

(22) Filed: Mar. 23, 2021

(51) Int. Cl. H01J 37/34; C23C 14/34; C23C 14/35

(52) U.S. Cl. CPC H01J 37/3405; H01J 37/3438; C23C 14/3492; C23C 14/35; H01J 2237/332

(57) ABSTRACT

A plasma processing system used for reactive sputtering may include multiple dual magnetron sputtering (DMS) components. Each DMS component may include a power supply coupled with two electrodes that switch between operation as a cathode and anode and are located within a plasma chamber. The power supply may be configured to operate as a transmitter or receiver power supply. A transmitter power supply may receive a phase-control-input signal that includes a phase offset value and may produce a phase-control-output signal and synchronization signal. The transmitter power supply may send the phase-control-output signal and synchronization signal to a receiver power supply, which may use these signals to synchronize electrode switching with the transmitter power supply and to apply the phase offset.

### BACKGROUND

### Field

The present invention relates generally to plasma-based sputtering, and more specifically to the use of control parameters for electrode phasing in reactive sputtering.

### Background

Sputtering is a technique for depositing a material onto a substrate that may be performed using a magnetron sputtering system. The material that is “sputtered” (e.g., ejected) from the magnetron is combined with a reactive gas at the substrate to form a compound at its surface. The reactive gas also reacts with the target surface, forming a compound there.

A common implementation of reactive sputtering is a dual magnetron sputtering (DMS) system. In a DMS system, two magnetrons within a plasma processing chamber serve as electrodes, alternating roles as cathodes and anodes based on voltages applied to the magnetrons. The voltage developed across the magnetrons is used to accelerate electrons within the plasma gas and ionize electrons from the gas.

Some systems may include multiple DMS components that operate in parallel, with each DMS component including two magnetrons that alternate roles as cathode and anode. In such systems, it may be desirable to change the phase difference and synchronize the alternation of the cathodes and anodes across DMS components to reduce the likelihood of arcing between adjacent pairs of magnetrons (which may occur if there is a large voltage difference between adjacent magnetrons). Such adjustments may require manual decoupling and recoupling of electrical cables between the DMS components, which may be cumbersome and may not support more than two phase differences between DMS components. A more efficient and flexible system for controlling the phasing of electrodes in a DMS system may be desirable.

### SUMMARY

Aspects disclosed herein address the above stated needs by implementing circuitry and signaling to enable flexible control of both the phase and polarity of electrodes in a plasma processing system that includes multiple DMS components without physically decoupling and re-coupling cables.

Aspects of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents and alternative constructions that fall within the spirit and scope of the invention as expressed in the claims.

An aspect may be characterized as a system for applying a first voltage at a first output of a first power supply, where the first voltage alternates between positive and negative relative to a second output of the first power supply during each of multiple cycles. The system includes a second power supply that is coupled to the first power supply by at least one communication line and includes a third output and a fourth output. The second power supply is configured to apply a third voltage at a third output that alternates between positive and negative relative to the fourth output during each of multiple cycles. The system includes at least one controller that is configured to receive a phase-control-input-signal and send a phase-control-signal and a synchronization signal to the second power supply to provide a phase offset between the first voltage and the second voltage to reduce a voltage difference between the second output and the third output.

Another aspect may be characterized as a method for causing a first power supply to apply a first voltage between a first output and a second output, where the first voltage alternates between positive and negative relative to the second output during each of multiple cycles. The method includes receiving a transmitter-set signal to set the first power supply as a transmitter. The method includes receiving a phase-control-input-signal and causing at least one controller to send a phase-control-signal and a synchronization signal to a second power supply to enable the first power supply to control a phase offset between the first voltage and a second voltage applied by the second power supply.

Yet another aspect may be characterized as a method for receiving a receiver-set signal at a second power supply to set the second power supply as a receiver. The method includes causing the second power supply to apply a first voltage between a first output and a second output, where the first voltage alternates between positive and negative relative to the second output during each of multiple cycles. The method includes receiving, at the second power supply, a phase-control-signal from the first power supply and causing at least one controller to control a phase offset between the first voltage and a second voltage applied by the second power supply.

Another aspect comprises system that includes a plasma processing chamber including at least a first electrode, a second electrode, a third electrode, and a fourth electrode. The system includes a first power supply including a first output coupled to the first electrode and a second output coupled to the second electrode, the first power supply configured to apply a first voltage at the first output that alternates between positive and negative relative to the second output during each of multiple cycles. The system includes a second power supply coupled to the first power supply by at least one communication line, the second power supply including a third output coupled to the third electrode and a fourth output coupled to the fourth electrode, the second power supply configured to apply a third voltage at the third output that alternates between positive and negative relative to the fourth output during each of multiple cycles. The system includes means for producing, in response to a phase-control-input-signal, a phase offset between the first voltage and the second voltage to reduce a voltage difference between the second output and the third output.

### BRIEF DESCRIPTION OF THE DRAWINGS

FIG. 1 depicts an example of a power supply system in a plasma processing system;

FIGS. 2A, 2B, and 2C are examples of waveforms that may be applied by the pulsed power system of FIG. 1;

FIG. 3 depicts an example embodiment of the power supply system of FIG. 1;

FIG. 4 depicts another example embodiment of the power supply system depicted in FIG. 1;

FIG. 5 depicts an example of magnetrons being utilized as electrodes;

FIG. 6 depicts aspects of the power supply systems disclosed herein;

FIG. 7 is an example of a method used for electrode phasing; and

FIG. 8 is an example of a computing component used for controlling aspects disclosed herein.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

DMS systems used for sputtering may include multiple DMS components, each of which may be coupled to dual electrodes (e.g., dual magnetrons) operating as opposite electrode pairs; that is, one magnetron operates as a cathode while the other operates as an anode. The voltage differential between the two electrodes drives the sputtering process. Each electrode pair periodically switches polarity such that the electrode functioning as a cathode switches to operating as an anode, and the electrode functioning as an anode switches to operating as a cathode. Such electrode polarity reversal (which may be referred to as a bipolar operation) is performed according to a configured frequency and duty cycle. It may be desirable that adjacent pairs of electrodes operate out of phase by approximately 180 degrees such that adjacent electrodes from different pairs are synchronized in terms of their polarity. Such an approach may reduce the voltage differential between adjacent magnetrons of different pairs, reducing the likelihood of arcing and plasma coupling.

Some DMS systems require human intervention to switch the polarity of a pair of magnetrons (e.g., effectively rotating the phase by 180 degrees) by physically disconnecting and reconnecting cables. Such an approach is inefficient, and only allows for two phases (based on whether the cables are connected in a first configuration for a first polarity or in a second configuration for a second polarity). In contrast, techniques described herein allow programmable, flexible electrode phase control for DMS systems without requiring physical cable changes.

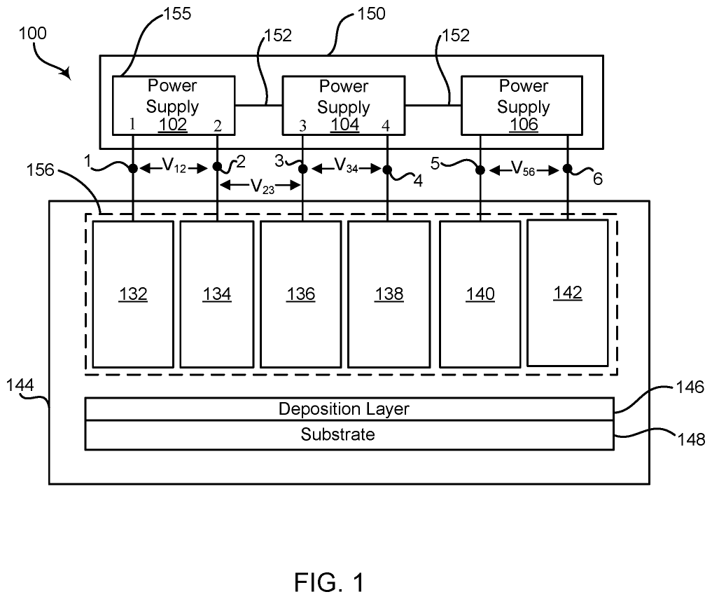

FIG. 1 depicts a plasma processing system 100 that may be used for depositing a material onto a substrate 148. As shown, the plasma processing system 100 comprises a power supply system 150 comprising power supplies 102, 104, 106, and each of the power supplies 102, 104, 106 may be connected to another one (or two) of the power supplies 102, 104, 106 via a communication link 152. As shown, power supply 102 includes a first output 1 and a second output 2; power supply 104 includes a third output 3 and a fourth output 4 and power supply 106 comprises a fifth output 5 and a sixth output 6. Electrodes 132, 134, 136, 138, 140, 142 may be referred to collectively as a set of electrodes 156. It should be recognized that the power supply system 150 may include a different quantity of power supplies and corresponding electrodes than shown in FIG. 1 without departing from the scope of the disclosure. It should also be recognized that each communication link 152 may be implemented by one or more wireline and/or wireless connections to enable synchronization and phase control between the power supplies 102, 104, 106.

As shown, the plasma processing system 100 comprises a plasma processing chamber 144, which is an enclosed container capable of maintaining a vacuum and containing a plasma during a sputtering process. The set of electrodes 156 may be located within plasma processing chamber 144 along with a substrate 148. The substrate 148 may be, for example, a silicon wafer, or another material. By controlling the output voltages applied to each pair of electrodes within the set of electrodes 156, the plasma processing system 100 may cause ionization of gases and sputtering of target material(s) within the plasma processing chamber 144, resulting in a deposition layer 146 upon the substrate 148.

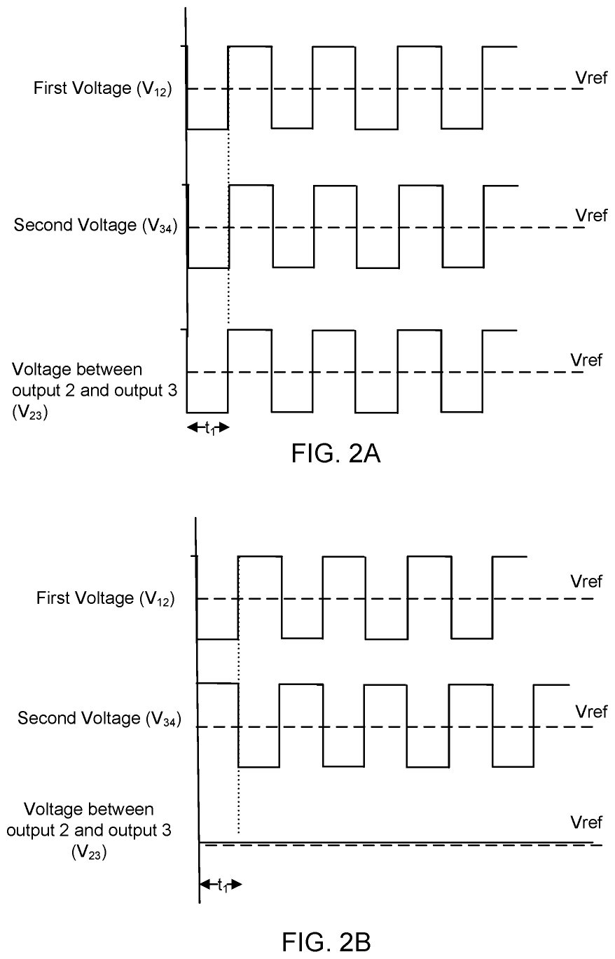

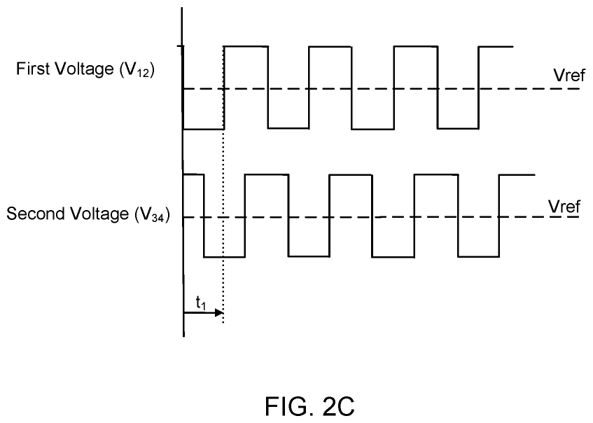

FIG. 2A depicts an example, of a mode of operation of the power supply system 150. As shown in FIG. 2A, a first voltage (V₁₂) applied to output 1 relative to output 2 may be synchronized to be in phase with a second voltage (V₃₄) applied to output 3 relative to output 4. During a time t₁, the voltage (V₁₂) applied to output 1 is negative relative to output 2; thus, electrode 132 (that is coupled to output 1) operates as a cathode relative to electrode 134, and as a consequence, the target material coupled to the electrode 132 will be sputtered. Similarly, during the time t₁, the voltage (V₃₄) applied to output 3 is negative relative to output 4; thus, electrode 136 (that is coupled to output 3) operates as a cathode relative to electrode 138, and as a consequence, the target material coupled to the electrode 136 will be sputtered. But as shown in FIG. 2A, when the power system 150 is operated in this manner, the voltage between output 2 and output 3 may be substantially similar to the first voltage (V₁₂) applied between the first output 1 and the second 2. As a consequence, the electrode in 134 could become an anode for both electrodes 132 and 136 when the intention is that electrode 134 operates as an anode for electrode 132 only. As shown in FIG. 2A, the first and second voltages may alternate between in polarity relative to a voltage Vref, which may be ground or another voltage potential.

As previously discussed, it may be desirable to control the phase between adjacent electrodes in different electrode pairs such that immediately adjacent cross-pair electrodes (e.g., electrodes coupled with different power supplies but that are physically immediately adjacent to each other, such as electrodes 134 and 136, electrodes 138 and 140) are alternated in tandem such that they are generally kept at the same or a similar voltage. It should be recognized that, although FIG. 2A depicts waveforms that result from the first power supply 102 and the second power supply 104, the power supply system 150 may generally include n power supplies and that the phase between any adjacent cross-pair electrodes may be adjusted.

Such coordinated switching may reduce or eliminate voltage differentials across cross-pair adjacent electrodes, thereby reducing the likelihood or arcing across pairs. In this case, adjacent pairs of electrodes (e.g., pair of electrodes 132, 134 which is adjacent to pair of electrodes 136, 138) may be switched such that their voltages are kept 180 degrees out of phase. Referring to FIG. 2B for example, the first voltage (V₁₂) applied to output 1 relative to output 2 may be synchronized to be 180 degrees out of phase with the second voltage (V₃₄) applied to output 3 relative to output 4. During a time t1, the first voltage (V₁₂) applied to output 1 is negative relative to output 2; thus, electrode 132 (that is coupled to output 1) operates as a cathode relative to electrode 134, and as a consequence, the target material coupled to the electrode 132 will be sputtered.

In contrast, during the time t1, the second voltage (V₃₄) applied to output 3 is positive relative to output 4; thus, electrode 138 (that is coupled to output 4) operates as a cathode relative to electrode 136, and as a consequence, the target material coupled to the electrode 138 will be sputtered. And as shown in FIG. 2B, when the power system 150 is operated in this manner, the voltage between output 2 and output 3 may be substantially the same. As a consequence, the target material coupled to electrodes 132 and 136 will sputter during the time t1, but the zero, or near zero, voltage difference between electrodes 134 and 136 will prevent or reduce arcing between immediately adjacent cross-pair electrodes 134, 136.

As described further herein, implementations of the power supply system 150 enable the phase between the first voltage V₁₂ and the second voltage V₃₄ to be controlled without removing and swapping the power cables of a power supply. Moreover, it is contemplated that the phase difference between the first voltage V₁₂ and the second voltage V₃₄ may be controlled to be any phase value between 0 and 180 degrees. Referring to FIG. 2C as an example, the first voltage (V₁₂) applied to output 1 relative to output 2 may be synchronized to be 90 degrees out of phase with the second voltage (V₃₄) applied to output 3 relative to output 4. During a time t1, the voltage (V₁₂) applied to output 1 is negative relative to output 2; thus, electrode 132 (that is coupled to output 1) operates as a cathode relative to electrode 134, and as a consequence, the target material coupled to the electrode 132 will be sputtered. In contrast, during a first half-cycle of the second voltage V₃₄ during t₁, the electrode 136 will operate as an anode relative to electrode 138, which will operate as a cathode relative to the electrode 136; thus, target material coupled to electrode 138 will be sputtered. During the second half-cycle of the second voltage V₃₄ (during the time t1), the electrode 136 will operate as a cathode relative to electrode 138, which will operate as a anode relative to the electrode 136; thus, target material coupled to electrode 136 will be sputtered.

With the phase scheme depicted in FIG. 2C, the voltages across each pair of electrodes are switched partially out of phase. In this case, the voltage difference across electrodes in one pair is, at times, the opposite of the voltage difference across electrodes in an adjacent pair, but at other times is the same as the voltage difference across electrodes in the adjacent pair. In this case, in the absence of other effects, a voltage difference may develop across cross-pair adjacent electrodes, which may result in arcing across pairs. Such arcing is generally undesirable, and thus it may be more common to use a 180-degree phase offset. In some cases, however, it may be desirable to use a phase offset other than 180 degrees to compensate for delays or other effects within the system. Moreover, it may be desirable to use a different phase offset at different electrode pairs, to enable finer-grained control of electrode switching and compensate for different delay times in the circuitry, for example.

To control electrode phasing across electrode pairs of the electrodes 156, power supplies 102, 104, 106 may be configured to communicate with each other, such as via the communication links 152. In some cases, one power supply may be configured to operate as a transmitter power supply and some or all of the other power supplies may be configured to operate as receiver power supplies. For example, power supply 104 may be configured to operate as a transmitter power supply, and power supplies 102, 106 may be configured to operate as receiver power supplies. A transmitter power supply may provide various control signals (discussed further herein) to the receiver power supplies to synchronize and control the phase of the set of electrodes 156.

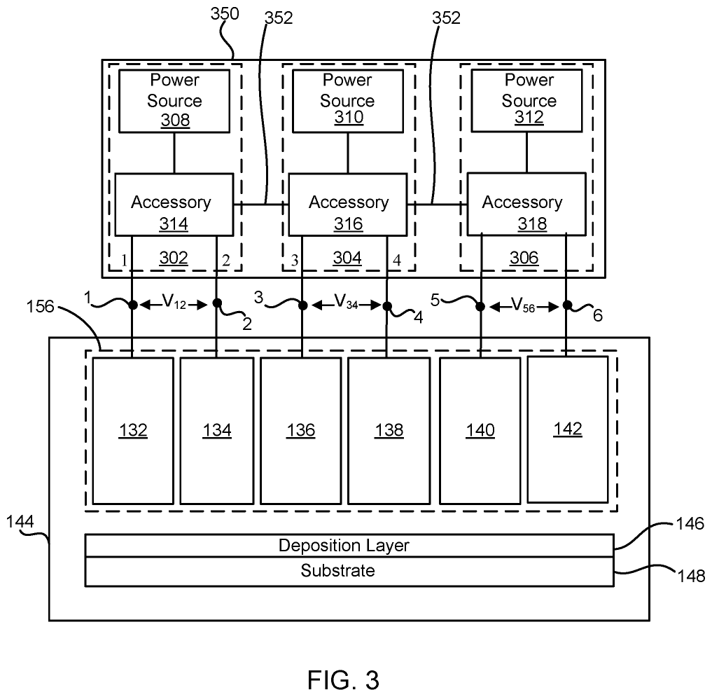

Referring next to FIG. 3 shown power supply system 350, which is a variation of the power supply system 150 described with reference to FIG. 1. As shown, each power supply 302, 304, 306 includes a power source 308, 310, 312 and a power accessory 314, 316, 318 coupled with the corresponding power source. Each power source 308, 310, 312 may supply a voltage (e.g., a DC voltage) to the corresponding power accessory 314, 316, 318, and each power accessory 314, 316, 318 may provide the DC voltage received from the corresponding power source 308, 310, 312 between two electrodes at one polarity during a first half of a cycle and then then apply the DC voltage at an opposite polarity between the two electrodes during a second half of the cycle, thereby alternately configuring each electrode as cathode or anode.

As discussed further herein, each power accessory 314, 316, 318 may include switching circuitry to switch the polarity of the outputs of each power supply, thereby switching the electrodes in each electrode pair from operating as cathodes to anodes or the reverse.

As previously discussed, it may be desirable to alternate the polarity of adjacent electrodes in different electrode pairs such that immediately adjacent cross-pair electrodes (e.g., electrodes coupled with different power supplies but that are physically immediately adjacent to each other, such as electrodes 134 and 136, electrodes 138 and 140) are alternated in tandem such that they are generally kept at the same or a similar voltage. Such coordinated switching may reduce or eliminate voltage differentials across cross-pair adjacent electrodes, thereby reducing the likelihood or arcing across pairs. In this case, adjacent pairs of electrodes (e.g., the pair of electrodes 132, 134 which is adjacent to the pair of electrodes 136, 138) may be switched such that the first voltage V₁₂ (the voltage of output 1 relative to output 2) is kept 180 degrees out of phase with the second voltage V₃₄ (the voltage of output 3 relative to output 4). For example, when electrode 134 is operating at a negative polarity relative to electrode 132, electrode 136 is operating at a negative polarity relative to electrode 136. Thus, the voltage between electrodes 134 and 136 may be reduced to prevent, or mitigate at least, against arcing and plasma coupling.

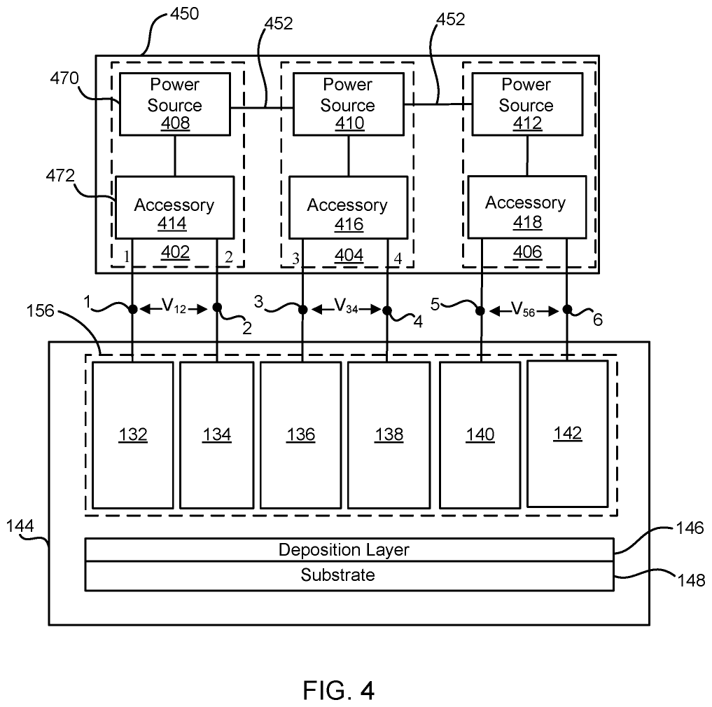

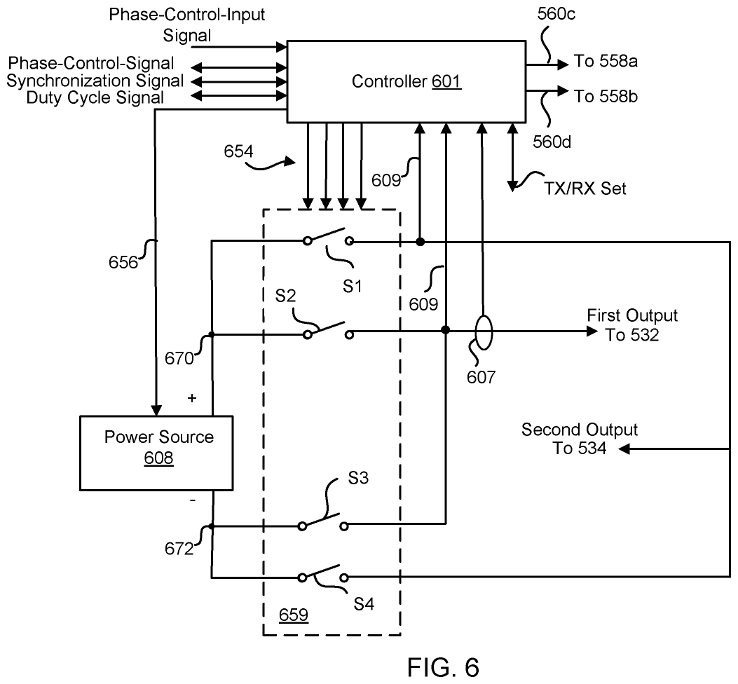

As shown in FIG. 3, the communication link 352 and control logic may be realized as a part of the accessories 314, 316, 318. But in alternative implementations, such as shown in FIG. 4, the communication link 452 and control logic of the power system 450 may be implemented within the power sources 408, 410, 412. Additional details regarding control signals and circuitry that may be used for electrode phasing are described with reference to FIG. 6. It should be recognized that the power sources (e.g., power source 308, 408) and accessories (e.g., accessories 314, 414) may be implemented within a common housing, e.g., housing 155). Or as depicted in FIGS. 3 and 4 the power sources (e.g., power source 308, 408) and accessories (e.g., accessories 314, 414) may be implemented in separate housings, e.g., housing 470 and housing 472).

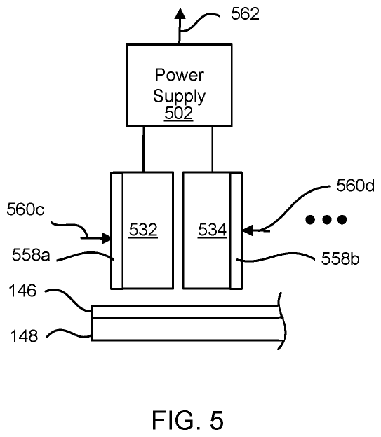

Referring next to FIG. 5, is a schematic block diagram that illustrates aspects of electrodes that are realized by magnetrons. For example, the power supply 502 and magnetrons 532, 534 may be used in place of any or all of the power supplies and electrode pairs depicted in FIGS. 1, 3, and 4. In operation, a voltage at each of the magnetrons 532, 534 may be measured to enable a voltage that is applied to the each of the magnetrons 532, 534 to be controlled. In addition, the rotation of controllers 558a, 558b may be controlled by control signals 560c, 560d. But it should be recognized that not all magnetrons are enabled with rotational capability.

Turning now to FIG. 6, shown are components that may be utilized to realize aspects of the power supply system 150, 350, 450 disclosed herein. For example, the components in FIG. 6 may be used to realize each of the power supplies 102, 104, 106, 302, 304, 306, 402, 404, 406. As shown, a controller 601 is operatively coupled to a power source 608 with a control signal 656 and coupled to a plurality of switching components 659 with switching control signals 654. The power source 608 may be used to implement power sources 308, 310, 312, 408, 410, 412, and the switching components 659 may be used to realize the accessories 314, 316, 318, 414, 416, 418. The controller 601 may be implemented within each of the power supplies 102, 104, 106, 302, 304, 306, 402, 404, 406. As an example, the controller 601 may be implemented as a part of the accessories 314, 316, 318 (e.g., to realize logic and the communication link 352 between accessories 314, 316, 318). As another example, the controller 601 may be implemented within each of the power sources 408, 410, 412, 608 (e.g., to realize logic and the communication link 452 between power sources 408, 410, 412). Alternatively, the controller 601 may be implemented within a central control system that is externally coupled to the power supplies 102, 104, 106.

The controller 601 in this embodiment generates the switching control signals 654 to operate the switching components 659 (which may be implemented in an H-bridge configuration). The controller may also optionally provide rotation control signals 560c, 560d (to control the rotation controllers 558a, 558b). As shown, the controller 601 may receive feedback from one or more current transducer(s) 607 and voltage pickups 609 (also referred to as voltage sensors 609) to receive an indication of the current and voltage at the electrodes or magnetrons 532, 534. The signals 654, 560c, 560d, 656 may be generated in response to the feedback from the sensed current and sensed voltage. In some embodiments, the switching components 659 may be configured and controlled as disclosed in U.S. patent application Ser. No. 13/104,942 or U.S. Pat. No. 8,391,025, the disclosures of which are incorporated herein by reference.

The power sources 308, 310, 312, 408, 410, 412, 608 may be realized by a controllable DC voltage source that is configured to apply a controllable DC voltage. The power sources 308, 310, 312, 408, 410, 412, 608 may be implemented by an ASCENT AMS power supply sold by Advanced Energy Industries, Inc., which may be modified to enable the synchronization and phase control described herein. The accessories 314, 316, 318, 414, 416, 418, and switching components 659 may be implemented by an ASCENT DMS dual-magnetron sputtering accessories sold be Advanced Energy Industries, Inc., which may be modified to enable the synchronization and phase control described herein.

The components in FIG. 6 may be configured to operate as a transmitter power supply or a receiver power supply in response to receiving an RX set (receiver-set) signal or a TX set (transmitter-set) signal, respectively. In some examples, the power supply systems 150, 350, 450 may include a single transmitter power supply and multiple receiver power supplies. In some examples, a power supply system may include multiple transmitter power supplies and multiple receiver power supplies. In operation, an operator of the power supply systems 150, 350, 450 may set one or more of the power supplies 102, 104, 106, 302, 304, 306, 402, 404, 406 as a transmitter power supply with the TX set signal, and the transmitter power supply may send phase-control signals, synchronization signals, and duty cycle signals to other power supplies via the communication link 152, 352, 452 configured to operate as receiver power supplies.

As described in more detail below, when configured as the transmitter power supply, the controller 601 may receive, from an external device, human, or other source, a phase-control-input-signal specifying one or more phase offsets, and the controller 601 may send (e.g., transmit, provide), to one or more receiver power supplies, a phase-control-signal and a synchronization signal via the communication link 152, 352, 452. Such signals may enable synchronized application of power to the electrodes and allow a user (or other source) to specify a phase offset for switching the electrodes of one or more receiver power supplies relative to the electrodes of the transmitter power supply. In some examples, the phase-control-input-signal may include a phase value. The phase value may be, for example, a value between 0 and 180 degrees, such as 0 degrees, 45 degrees, 90 degrees, 135 degrees, 180 degrees, or another value.

As shown, the controller 601 may be configured to control the operation of the power source 608 and/or switching components 659 of power accessories. For example, the controller 601 may provide the control signal 656 to the power source 608 via conductive line. The control signal may indicate a magnitude of the first voltage (V₁₂) and a magnitude of the second voltage second voltage (V₃₄) for power source 608 to provide to a power accessory. And the power source 608 may provide a DC voltage with a magnitude to the switching components 659 of the power accessories 314, 414 that is based on the control signal 656.

The controller 601 may control the switching components 659 (S1, S2, S3, S4) to apply power to the electrodes (e.g., magnetrons 532, 534). In some examples, at least two of the switches S1, S2, S3, S4 are closed at substantially the same time, and may cause the first output to alternate between positive and negative values relative to the second output during each of multiple cycles. For example, assuming a top node 670 of the power source 608 is positive and a bottom node 672 of the power source 608 is negative, when S2 and S4 are controlled to be closed and S1 and S3 are controlled to be open, the first output will be positive (e.g., so the magnetron 532 will operate as an anode) and the second output will be negative (e.g., so the magnetron 534 will operate as a cathode), and when S2 and S4 are open and S1 and S3 are closed, the first output will be negative (e.g., so the magnetron 532 will operate as a cathode) and the second output will be positive (e.g., so the magnetron 534 will operate as an anode).

The controller 601 may control the timing of activating and deactivating switches S1, S2, S3, S4 based on, or in response to, one or more control signals received from controller 506. For example, controller 506 may provide (based upon the phase-control-signal) control signals to a power accessory that indicate a timing for switching S1, S2, S3, and S4. In addition, the duty cycle may also be controlled. The duty cycle may be 50-50 (e.g., pairs of switches are activated for the same amount of time in each cycle), for example, or 40-60 (e.g., one pair of switches is activated for 40% of the time and the other pair of switches is activated for the remaining 60% of the time), or may be another duty cycle value.

When operating as a receiver power supply, the controller 601 may receive phase-control-signals, synchronization signals, and duty cycle signals via the communication link 152, 352, 452. In some examples, the controller 601 may generate (or receive) a synchronization signal as a periodic waveform, such as a square wave or sinusoid, that may enable synchronization (with or without phase offset) with other power supplies.

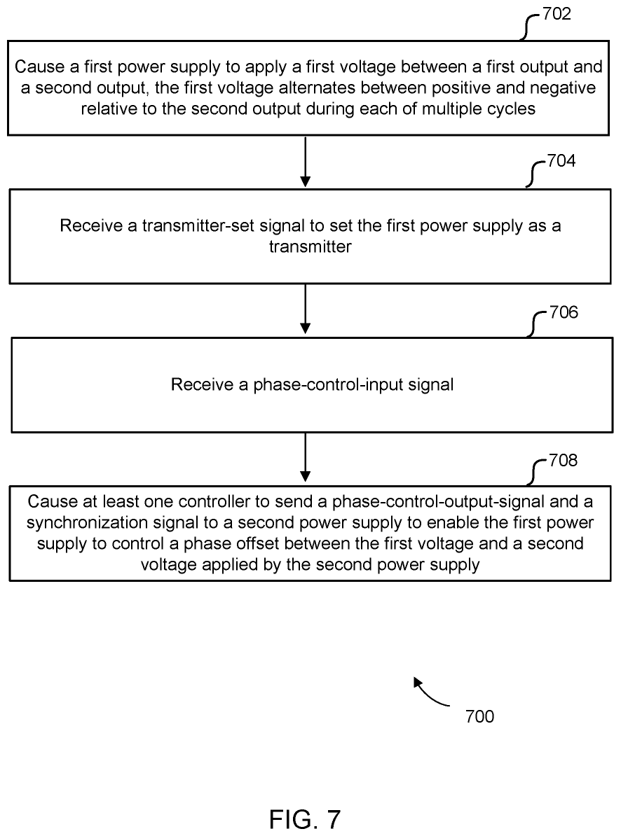

Referring next to FIG. 7, shown is a process 700 for electrode phasing using control signals. The process 700 may be performed by a power supply, such as power supply 102, 104, 106, 302, 304, 306, 402, 404, 406 such as by executing logic embodied in a software program and/or dedicated hardware within a controller, such as controller 601. As shown, at 702, the controller 601 may cause a first power supply (e.g., a transmitter power supply) to apply a first voltage (e.g., V₁₂) between a first output (e.g., first output 1) and a second output (e.g., second output 2), where the first voltage alternates between positive and negative at the first output relative to the second output during each of multiple cycles (e.g., cycles as depicted in FIGS. 2A, 2B, and 2C).

At 704, the controller 601 may receive a transmitter-set signal via one or more communication lines (e.g., conductive, fiber optic, and/or wireless communication links) to set the first power supply as a transmitter.

At 706, the controller 601 may receive a phase-control-input signal (e.g., via one or more conductive lines).

At 708, the controller 601 may cause a phase-control-signal and a synchronization signal to be sent (e.g., via one or more conductive lines) to a second power supply (e.g., receiver power supply) to enable the first power supply to control a phase offset between the first voltage (e.g., V₁₂) and a second voltage (e.g., V₃₄) applied by the second power supply.

The steps of a method or algorithm described in connection with the embodiments disclosed herein may be embodied directly in hardware, in processor executable instructions encoded in non-transitory processor readable medium, or in a combination of the two. A software module (including non-transitory processor executable instructions) may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

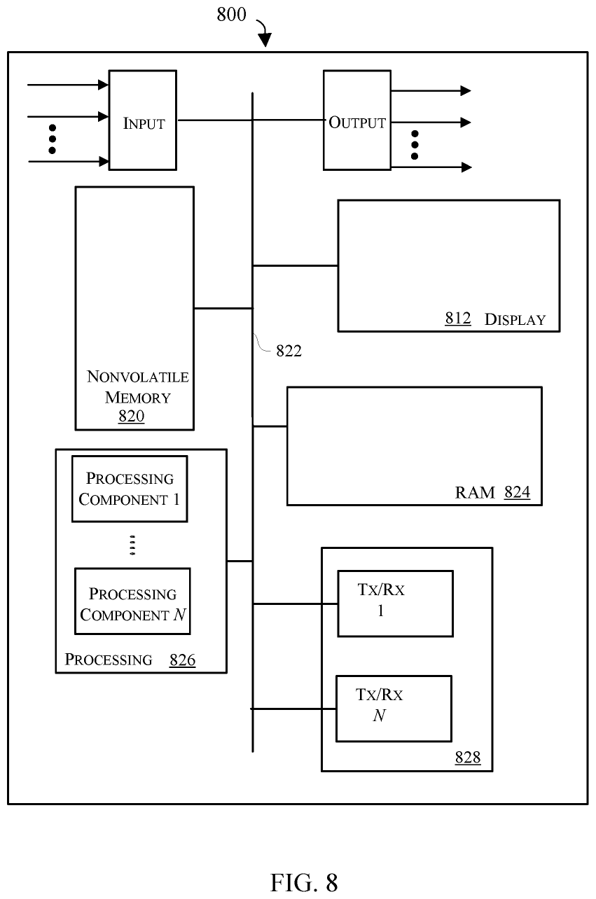

Referring to FIG. 8 for example, shown is computing component 800 depicting physical components that may be utilized to realize a controller (e.g., 601) according to an exemplary embodiment. The depicted computing component 800 may be duplicated and instantiated is each power supply 102, 104, 106; each power source 308, 310, 312, 408, 410, 412; and/or each accessory 314, 316, 318, 414, 416, 418. It is also contemplated that the computing component 800 may be implemented as a centralized controller. In some implementations, the dimensions of components depicted in FIG. 8 enable the computing component 800 to be implemented as a system on a chip (SoC), and the large scale production of computing components (such as the computing component 800) is enabling instances of the computing component 800 to be duplicated at low cost to be used throughout the power processing and plasma processing systems disclosed herein.

As shown, in this embodiment a display portion 812 and nonvolatile memory 820 are coupled to a bus 822 that is also coupled to random access memory (“RAM”) 824, a processing portion (which includes N processing components) 826, and a transceiver component 828 that includes N transceivers. Although the components depicted in FIG. 8 represent physical components, FIG. 8 is not intended to be a detailed hardware diagram; thus, many of the components depicted in FIG. 8 may be realized by common constructs or distributed among additional physical components. Moreover, it is contemplated that other existing and yet-to-be developed physical components and architectures may be utilized to implement the functional components described with reference to FIG. 8.

This display 812 generally operates to provide a user interface for a user, and in several implementations, the display 812 is realized by a touchscreen display. In some implementations, the display 812 may enable a user to set a power supply as a transmitter power supply or a receiver power supply. It is also contemplated that a user may provide other setpoint information via the display 812 (e.g., phase, voltage, current, and/or power). The display 812 may also present information about the power (e.g., voltage, current, phase) applied by a power supply 102, 104, 106, 302, 304, 306, 402, 404, 406. In general, the nonvolatile memory 820 is non-transitory memory that functions to store (e.g., persistently store) data and processor executable code (including executable code that is associated with effectuating the methods described herein). In some embodiments for example, the nonvolatile memory 820 includes bootloader code, operating system code, file system code, and non-transitory processor-executable code to facilitate the execution of the methods described with reference to FIGS. 1-7.

In many implementations, the nonvolatile memory 820 is realized by flash memory (e.g., NAND or ONENAND memory), but it is contemplated that other memory types may be utilized. Although it may be possible to execute the code from the nonvolatile memory 820, the executable code in the nonvolatile memory is typically loaded into RAM 824 and executed by one or more of the N processing components in the processing portion 826.

The N processing components in connection with RAM 824 generally operate to execute the instructions stored in nonvolatile memory 820 to enable the power supply systems 150, 350, 450 to achieve one or more objectives. For example, non-transitory processor-executable instructions to effectuate the methods described with reference to FIG. 7 may be persistently stored in nonvolatile memory 820 and executed by the N processing components in connection with RAM 824. As one of ordinary skill in the art will appreciate, the processing portion 826 may include a video processor, digital signal processor (DSP), graphics processing unit (GPU), and other processing components.

The input component may operate as a part of a user interface and/or an interface to receive signals that are indicative of a phase-control-input signal, phase-control-signal, synchronization signal and/or duty cycle signal. The signals received at the input component may also include setpoint information such as voltage, current, and/or power. The output component generally operates to provide one or more analog or digital signals to effectuate an operational aspect of a power supply. For example, the output portion may provide the phase-control-signal, synchronization signal, and duty cycle signal to cause a power supply to effectuate some of the methodologies described herein including with reference to FIG. 6. In some embodiments, the input and output components may be used to realize the communication links 152, 352, 452 described herein.

The depicted transceiver component 828 includes N transceiver chains, which may be used for communicating with external devices via wireless or wireline networks. Each of the N transceiver chains may represent a transceiver associated with a particular communication scheme (e.g., WiFi, Ethernet, Profibus, etc.). The transceiver chain(s) may be used to implement the communication links 152, 352, 452, and if so, the signals that are indicative of a phase-control-input signal, phase-control-signal, synchronization signal and/or duty cycle signal may be transmitted and received via the transceiver chains.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

1. A power supply system, comprising:
a first power supply comprising a first output and a second output, the first power supply configured to apply a first voltage at the first output that alternates between positive and negative relative to the second output during each of multiple cycles;
a second power supply coupled to the first power supply by at least one communication line, the second power supply comprising a third output and a fourth output, the second power supply configured to apply a second voltage at the third output that alternates between positive and negative relative to the fourth output during each of multiple cycles; and
at least one controller configured to:
receive a phase-control-input-signal; and
send a phase-control-signal and a synchronization signal to the second power supply to provide a phase offset between the first voltage and the second voltage to reduce a voltage difference between the second output and the third output.

2. The power supply system of claim 1, wherein the at least one controller includes:
a first controller configured to receive:
a transmitter-set signal to set the first power supply as a transmitter; and
the phase-control-input-signal;
wherein the first controller is configured to send, in response to receiving the transmitter-set signal, the phase-control-signal and the synchronization signal to the second power supply; and
a second controller configured to receive the phase-control-signal and the synchronization signal.

3. The power supply system of claim 1, wherein each of the first power supply and the second power supply includes a power source and power accessory.

4. The power supply system of claim 3, wherein each of the first power supply and the second power supply include a power source and a power accessory, wherein the power source and the power accessory are one of: integrated within a common housing or separated into separate housings.

5. The power supply system of claim 4, wherein the power source includes a direct current (DC) power source and the power accessory includes switches to switch power from the DC power source, and wherein the at least one controller controls a timing of the switches in the second power supply in response to both the phase-control-signal and the synchronization signal.

6. The power supply system of claim 1, wherein the least one controller is configured to receive the phase-control-input-signal as a phase value between 0 and 180 degrees.

7. The power supply system of claim 1, wherein the at least one controller is configured to send a phase-control-signal to a third power supply to rotate a phase offset of the third power supply if there is no power output from the second power supply.

8. A non-transitory memory comprising non-transitory instructions that are at least one of executable by a processor to execute a method and accessible by a field programmable gate array to configure the field programmable gate array to execute the method, the method comprising:
causing a first power supply to apply a first voltage between a first output and a second output, the first voltage alternates between positive and negative relative to the second output during each of multiple cycles;
receiving a transmitter-set signal to set the first power supply as a transmitter;
receive a phase-control-input-signal; and
causing at least one controller to send a phase-control-signal and a synchronization signal to a second power supply to enable the first power supply to control a phase offset between the first voltage and a second voltage applied by the second power supply.

9. The non-transitory memory of claim 8, wherein the non-transitory instructions include instructions to send a duty cycle signal to the second power supply.

10. A non-transitory memory comprising non-transitory instructions that are at least one of executable by a processor to execute a method and accessible by a field programmable gate array to configure the field programmable gate array to execute the method, the method comprising:
receiving a receiver-set signal at a second power supply to set the second power supply as a receiver;
causing the second power supply to apply a first voltage between a first output and a second output, the first voltage alternates between positive and negative relative to the second output during each of multiple cycles;
receiving, at the second power supply, a phase-control-signal from the first power supply; and
causing at least one controller to control a phase offset between the first voltage and a second voltage applied by the second power supply.

11. The non-transitory memory of claim 10, wherein the non-transitory instructions include instructions to receive a duty cycle signal at the second power supply.

12. A plasma processing system comprising:
a plasma processing chamber comprising at least a first electrode, a second electrode, a third electrode, and a fourth electrode;
a first power supply comprising a first output coupled to the first electrode and a second output coupled to the second electrode, the first power supply configured to apply a first voltage at the first output that alternates between positive and negative relative to the second output during each of multiple cycles;
a second power supply coupled to the first power supply by at least one communication line, the second power supply comprising a third output coupled to the third electrode and a fourth output coupled to the fourth electrode, the second power supply configured to apply a third voltage at the third output that alternates between positive and negative relative to the fourth output during each of multiple cycles; and
means for producing, in response to a phase-control-input-signal, a phase offset between the first voltage and the second voltage to reduce a voltage difference between the second output and the third output.

13. The plasma processing system of claim 12, wherein the means for producing comprises:
a first controller configured to receive:
a transmitter-set signal to set the first power supply as a transmitter; and
a phase-control-input-signal;
wherein the first controller is configured to send, in response to receiving the transmitter-set signal, the phase-control-signal and a synchronization signal to the second power supply; and
a second controller configured to receive the phase-control-signal and the synchronization signal.

14. The plasma processing system of claim 13, wherein each of the first power supply and the second power supply includes a power source and power accessory.

15. The plasma processing system of claim 14, wherein each of the first power supply and the second power supply include a power source and a power accessory, wherein the power source and the power accessory are one of: integrated within a common housing or separated into separate housings.

16. The plasma processing system of claim 15, wherein the power source includes a direct current (DC) power source and the power accessory includes switches to switch power from the DC power source, and wherein the means for producing comprises a controller to control a timing of the switches in the second power supply in response to both the phase-control-signal and the synchronization signal.

17. The plasma processing system of claim 13, wherein the second controller is configured to receive the phase-control-input-signal as a phase value between 0 and 180 degrees.

18. The plasma processing system of claim 13, wherein the first controller is configured to send another phase-control-signal to a third power supply to rotate a phase offset of the third power supply if there is no power output from the second power supply.
